(19) United States
(12) Patent Application Publication
(10) Pub. No.: US 2009/0188701 A1
(43) Pub. Date: Jul. 30, 2009

(54) Inorganic powder, resin composition filled with the powder and use thereof

(76) Inventors: Hiroshi Tsuzuki, Toyama (JP); Hisao Kogoi, Toyama (JP); Jun Tanaka, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/585,446

(22) PCT Filed: Jan. 7, 2005
(86) PCT No.: PCT/JP05/00431

§ 371 Date: Jul. 7, 2006

Related U.S. Application Data
(60) Provisional application No. 60/535,806, filed on Jan. 13, 2004.

(30) Foreign Application Priority Data
Jan. 8, 2004 (JP) 2004-3377
Mar. 23, 2004 (JP) 2004-85269

(51) Int. Cl. H05K 1/02; B32B 9/00; B32B 27/00; C08K 3/22

(52) U.S. Cl. 174/252; 428/402; 428/220; 524/430

(57) ABSTRACT

The present invention relates to an inorganic powder having a frequency-size distribution with multiple peaks, wherein the peaks are present at least in the particle size regions from 0.2 to 2 μm and from 2 to 63 μm, preferably with the maximum particle size being 63 μm or less, the average particle size being from 4 to 30 μm, and the mode size being from 2 to 35 μm. The inorganic powder of the present invention is useful as a filler for a high thermally conductive member in electronic component-mounted circuit board required to have electrical insulating property and heat radiating performance, in that a heat radiating member comprising the powder can have thermal conductivity, the powder can provide a resin composition having excellent withstand voltage characteristics for forming an insulative composition into a thin film and can be filled in the resin composition at a high density so as to improve heat radiating performance of the resin composition.

### CROSS-REFERENCE TO RELATED APPLICATIONS

This is an application filed pursuant to 35 U.S.C. Section 111(a) with claiming the benefit of U.S. provisional application Ser. No. 60/535,806 filed Jan. 13, 2004 under the provision of 35 U.S.C. 111(b), pursuant to 35 U.S.C. Section 119(e)(1).

### TECHNICAL FIELD

The present invention relates to a resin composition having thermal conductivity, which is useful as a high thermally conductive member, and to a use of the resin composition such as electronic component-mounted circuit board required to have electrical insulating property and a high thermal conduction. The present invention also relates to an inorganic powder having high thermal conductivity, which is filled as a heat conducting filler in the resin composition.

### BACKGROUND ART

In recent years, a circuit board having mounted thereon electronic components such as semiconductor element is being used for electronic control devices in various fields, for example, in home electric appliances and automobile electric equipment. With abrupt progress toward miniaturization of devices, the demand for higher integration and higher functionality of the circuit board is more and more increasing and in turn, the quantity of heat locally generated on the circuit or the like tends to increase. Since the heat generation and heat accumulation have an adverse effect on the durability of the circuit or the like, the circuit board is required to have higher thermal conduction in addition to the electrical reliability such as electrical insulation and at present, studies are being made on the improvement of thermal conduction and on methods for transferring/thermally conducting not only for the circuit board body and encapsulant but also for the members such as insulating adhesive layer.

For the heat radiation, a method of transferring and conducting heat by assembling a metal-made fin or thermal radiation plate having high thermal conductivity and a circuit board or the like to come into contact with each other is generally employed. However, if these two members are electrified or short-circuited at the joint part, the circuit is destroyed. Therefore, a resin composition layer comprising a known organic polymer composition having high electrical insulating property is generally interposed therebetween to establish isolation. However, the organic polymer composition in general has a low coefficient of thermal conductivity and when used alone, the performance as a high thermally conductive member is low.

As for the method of imparting thermal conductivity to the resin composition comprising an organic polymer composition or the like, a technique of filling, as a heat conducting filler, an inorganic powder having high thermal conductivity is conventionally known. Incidentally, the inorganic powder serves also as a filler of imparting functions such as flame resistance and electrical insulation. In particular, a spherical inorganic powder is excellent in view of fillability and flowability and therefore, this is already often used in practice as a filling material for the high thermally conductive member or semiconductor encapsulant of a circuit board. For example, a spherical aluminum oxide powder having a high coefficient of thermal conductivity is used as a high thermally conductive filler and a spherical silica powder is used as a semiconductor encapsulant filler because of its high purity.

As for the method of obtaining a spherical inorganic powder, a technique of introducing a raw material inorganic powder or a slurry thereof into a high-temperature flame to make a melted state and spheroidizing it by using the surface tension is known (see, for example, JP-A-2001-19425). Also, a metal is sometimes used as the raw material and in this case, high temperature oxidation and melting spheroidization of the metal simultaneously proceed in parallel (see, for example, JP-A-1993-193908).

When the spherical inorganic powder having good spherical state, so-called high spheroidicity, is filled in a resin compound, the viscosity (hereinafter referred to as a “resin compound viscosity”) as an index for high fillability or flowability is low and therefore, resin defects such as void are less generated. By virtue of such an advantage, this powder has the preference as a filler promising to enhance the thermal conduction of the resin compound, despite its expensiveness. On the other hand, a relatively inexpensive inorganic powder having a low spheroidicity or having corners like a ground powder is relatively high in the resin compound viscosity and causes a serious flow failure when heat-curing the compound to a high viscosity, and resin defects are readily generated. When many resin defects are present, the strength to dielectric breakdown voltage (hereinafter referred to as “dielectric breakdown strength”), which is an index for electrical reliability and breakdown voltage characteristics, tends to decrease.

The inorganic powder generally has a hydrophilic surface and therefore, exhibits low affinity for the polymer composition working out to the compound, such as organic polymer composition as represented by epoxy resin or silicone polymer composition. In particular, the spherical inorganic powder is weak in the bonding or adhering property because of its smooth surface and susceptible to interfacial failure and reduction of the dielectric breakdown strength. In order to enhance the adhering property to the resin composition even in such a case, a technique of surface-treating the powder with a silane-based coupling agent or the like and rendering the surface hydrophobic is generally known (see, for example, JP-A-1993-335446, JP-A-2001-240771 and Catalogue of NUC silane coupling agents produced by Nippon Unicar Company Limited).

The resin composition for the high thermally conductive member of a circuit board is demanded to have high thermal conduction while maintaining the flexibility and breakdown voltage characteristics inherent in the organic polymer composition and the like. When an inorganic powder having high thermal conductivity is filled at a high density so as to obtain high thermal conduction, this leads to reduction of breakdown voltage characteristics and flexibility due to interfacial failure or generation of resin defects. Therefore, in conventional techniques, an expensive spherical inorganic powder having good flowability (that is, low resin compound viscosity), high fillability and high spheroidicity is selected and used with preference. Also, a technique of using the spherical inorganic powder after controlling it to a specific particle size distribution or particle property by a classification/mixing treatment and improving the adhering property or the like by additional processing such as surface treatment is known (see, for example, JP-A-2001-139725 and JP-A-2003-137627).

In other words, the inorganic powder having relatively poor flowability (that is, high resin compound viscosity) such as ground powder or low-spheroidicity powder available and producible at a relatively low cost cannot be used because high-density filling can be hardly attained and serious decrease in the breakdown voltage characteristics occurs due to generation of resin defects and the like, as a result, a resin composition having high thermal conduction and high breakdown voltage characteristics cannot be obtained in conventional techniques by using such a low-cost inorganic powder.

### DISCLOSURE OF THE INVENTION

An object of the present invention is to provide a thermally conducting inorganic powder capable of being filled in a resin component at a high density large enough to enhance the thermal conduction and forming a thin film-like insulating resin composition (hereinafter referred to as a “thin-film resin sheet”) having high breakdown voltage characteristics, and provide a resin composition usable as a high thermally conductive member of a circuit board and the like required to have electrical insulating property and high thermal conduction.

The present inventors have made ardent studies in view of the above circumstances and completed the present invention based on the findings that when a thermally conducting inorganic powder having a specific particle size distribution and preferably being subjected in advance to a surface-hydrophobing treatment is used, although a low-spheroidicity inorganic powder is prone to give a high resin compound viscosity, the powder can be filled at a high density in a resin and can express high thermal conductivity, and that the resin composition can ensure high dielectric breakdown strength when a thin-film resin sheet is formed of the composition.

More specifically, the present invention comprises the following embodiments.

(1) An inorganic powder having a frequency-size distribution with multiple peaks, wherein the peaks are present at least in the particle size regions from 0.2 to 2 μm and from 2 to 63 μm.

(2) The inorganic powder as described in (1), wherein the maximum particle size is 63 μm or less, the average particle size is from 4 to 30 μm, and the mode size is from 2 to 35 μm.

(3) The inorganic powder as described in (1), wherein the percentage of particles having a particle size of less than 2 μm is from 0 to 20 mass % and the mode size of particles having a particle size of less than 2 μm is from 0.25 to 1.5 μm.

(4) The inorganic powder as described in (1), wherein the percentage of particles having a particle size of 8 μm or more is from 44 to 90 mass %.

(5) The inorganic powder as described in (1), wherein the percentage of particles having a particle size of from 2 to 8 μm is from 0 to 15 mass %.

(6) The inorganic powder as described in (1), wherein the percentage of particles having a particle size of from 2 to 8 μm is from 32 to 45 mass %.

(7) The inorganic powder as described in (1), wherein the spheroidicity is from 0.68 to 0.95 and the spheroidization ratio is from 0.63 to 0.95.

(8) The inorganic powder as described in (1), wherein the spheroidicity of particles having a particle size of less than 2 μm is from 0.5 to 0.95 and the spheroidization ratio thereof is from 0 to 0.9.

(9) The inorganic powder as described in (1), wherein the spheroidicity of particles having a particle size of 8 μm or more is from 0.7 to 0.95 and the spheroidization ratio thereof is from 0.7 to 0.95.

(10) The inorganic powder as described in (1), wherein the thermal conductivity of the inorganic powder in the single crystal state is 30 W/m.K or more.

(11) The inorganic powder as described in any one of (1) to (10), which is an alumina powder.

(12) The inorganic powder as described in (11), wherein the a alumina crystal phase fraction of the alumina powder is from 30 to 75 mass%.

(13) The inorganic powder as described in (11), wherein the α alumina crystal phase fraction of the particle of less than 2 μm is from 90 to 100 mass %.

(14) The inorganic powder as described in (11), wherein the α alumina crystal phase fraction of the particle of 8 μm or more is from 30 to 70 mass %.

(15) The inorganic powder as described in (1), wherein the content of metal aluminum is 0.05 mass % or less.

(16) The inorganic powder as described in (1), wherein the content of sulfate ion is 15 ppm or less.

(17) The inorganic powder as described in (1), wherein the content of chlorine ion is 15 ppm or less.

(18) The inorganic powder as described in (1), wherein the content of Fe₂O₃ is 0.03 mass % or less.

(19) The inorganic powder as described in (1), which contains substantially no particles of less than 50 nm.

(20) The inorganic powder as described in (1), which is subjected to surface-hydrophobing treatment with at least one surface-treating agent selected from silane-based coupling agent and titanate-based coupling agent.

(21) A resin composition filled with the inorganic powder described in any one of (1) to (20).

(22) The resin composition as described in (21), wherein from 50 to 90 mass % of the inorganic powder is filled.

(23) The resin composition as described in (21) or (22), wherein when the resin composition is formed into a thin-film insulating resin composition with a thickness of 40 to 90 μm, the dielectric breakdown strength as measured by a dielectric breakdown voltage test prescribed in JIS C2110 is 39 kV/mm or more.

(24) A circuit board for mounting on automobiles, using the resin composition described in any one of (21) to (23).

(25) A circuit board for mounting on electronic devices, using the resin composition described in any one of (21) to (23).

(26) A high thermally conductive member for installation in electronic devices, using the resin composition described in any one of (21) to (23).

(27) A high thermally conductive member for electronic components, using the resin composition described in any one of (21) to (23).

(28) The high thermally conductive member as described in (26) or (27), which is in a sheet form.

(29) The high thermally conductive member as described in (26) or (27), which is in a form of gel or paste.

(30) The high thermally conductive member as described in (26) or (27), which is an underfill-agent type member.

(31) The high thermally conductive member as described in (26) or (27), which is applied by coating onto a heating portion of an elemental device.

(32) A metal-based circuit board, a metal core-type circuit board and a structure body thereof, wherein the resin composition described in any one of (21) to (23) is used as a high thermally conductive member serving also as an insulating adhesive layer or the like.

(33) A structure body of a high thermally conductive metal member-integrated electronic component, wherein a heat generating electronic component and a high thermally conductive metal member are bonded by using the high thermally conductive member described in any one of (26) to (31).

(34) An LED circuit board using the high thermally conductive member described in any one of (26) to (31).

(35) An automobile using the circuit board described in (32) or (34) or the structure body described in (32) or (33).

(36) An electronic product using the circuit board described in (32) or (34) or the structure body described in (32) or (33).

(37) A light indicator using the circuit board described in (32) or (34) or the structure body described in (32) or (33).

(38) A display device using the circuit board described in (32) or (34) or the structure body described in (32) or (33).

### DETAILED DESCRIPTION OF THE INVENTION

The embodiments of the present invention is described in detail below.

In a preferred embodiment of the present invention, the inorganic powder has a specific particle size distribution, which enables high-density filling in a resin composition.

The inorganic powder according to a preferred embodiment of the present invention is preferably a powder having multiple peaks (that is, having two or more peaks) in the frequency-size distribution, where the maximum particle size is preferably 63 μm or less, the average particle size is preferably from 4 to 30 μm, more preferably from 4 to 16 μm, the mode size is preferably from 2 to 35 μm, more preferably from 7 to 20 μm. More specifically, it is preferable that in the frequency-size distribution with multiple peaks, at least one peak be present in the particle size region from 0.2 to 2 μm and also at least one peak in the particle size region from 2 to 63 μm, that the spheroidicity be from 0.68 to 0.95, more preferably from 0.68 to 0.80, and that the spheroidization ratio be from 0.63 to 0.95, more preferably from 0.63 to 0.77.

By having multiple peaks, a larger number of fine particles intrude into a void between coarse particles and this is considered to accelerate closest filling. Also, by having peaks in the above-mentioned particle size regions, the closest filling is further accelerated.

As for the particle component contained in the particle size region of 0.2 to 2 μm, assuming that the inorganic powder is 100 mass %, the percentage of particles having a particle size of less than 2 μm is preferably from 0 to 25 mass %, more preferably from 0 to 11 mass % or from 13 to 25 mass %, the mode size is preferably from 0.25 to 1.5 μm, the spheroidicity is preferably from 0.5 to 0.95, more preferably from 0.8 to 0.85, and the spheroidization ratio is preferably from 0 to 0.9, more preferably from 0 to 0.5.

As for the characteristic feature of the particle component contained in the particle size region of 2 to 63 μm, the percentage of particles having a particle size of 8 μm or more is preferably from 44 to 90 mass %, more preferably from 48 to 86 mass %, the spheroidicity is preferably from 0.7 to 0.95, more preferably from 0.7 to 0.8, still more preferably from 0.7 to 0.78, and the spheroidization ratio is preferably from 0.7 to 0.9, more preferably from 0.7 to 0.75.

Furthermore, the percentage of particles contained in the particle size region of 2 to 8 μm is preferably from 0 to 15 mass % or from 32 to 45 mass %, more preferably from 4 to 15 mass %, or from 34 to 45 mass %.

When the inorganic powder is adjusted to have such a particle size distribution by mixing or the like, even an inorganic powder with low spheroidicity can be made to have high filling degree.

Examples of the inorganic powder which can be used include aluminum oxide, aluminum nitride, crystalline silica, magnesia, boron nitride, silicon nitride, beryllia, silicon carbide, boron carbide, titanium carbide and diamond, but an inorganic powder capable of satisfying both thermal conductivity (coefficient of thermal conductivity) and insulation (volume specific resistance value) is preferably used, and an inorganic powder where in the single crystal state, the coefficient of thermal conductivity is 30 W/m.K or more and the volume specific resistance value is 1×10¹⁴ Ω.cm or more is more preferably used.

For example, aluminum oxide, aluminum nitride, magnesia, boron nitride and beryllia can be employed as a particularly preferred inorganic powder.

When considering moisture resistance, chemical stability and safety of use, the inorganic powder of the present invention is most preferably aluminum oxide or aluminum nitride, but when profitability is taken account of, aluminum oxide is preferred. The inorganic powder can be used either in a single form or in a mixed form.

The aluminum oxide powder is preferably a spherical aluminum oxide powder passed through a spheroidization step of the Verneuil's method starting from an aluminum oxide powder obtained by sintering or electrofusing Bayer aluminum hydroxide, a low-sodium fine particulate aluminum oxide powder produced from Bayer aluminum oxide, or a high-purity fine particulate aluminum oxide powder produced by an ammonia alum thermal decomposition method, an aluminum alkoxide hydrolysis method, an aluminum submerged discharge method or other methods, but the present invention is not limited thereto.

The aluminum nitride powder is preferably an aluminum nitride powder produced by a direct nitridation method, a reduction nitridation method or the like, but the present invention is not limited thereto.

The aluminum oxide and aluminum nitride each may be used either in a single form or in a mixed form. Also, a plurality of aluminum oxides or aluminum nitrides obtained by various production methods may be used in combination.

The inorganic powder according to a preferred embodiment of the present invention is preferably an alumina powder where the α alumina crystal phase fraction measured by X-ray diffraction analysis is from 30 to 75 mass %, more preferably from 30 to 67 mass %.

Furthermore, the inorganic powder according to a preferred embodiment of the present invention is preferably an alumina powder where the ax alumina crystal phase fraction of the powder in the particle size region of less than 2 μm is from 90 to 100 mass %, more preferably from 95 to 99 mass %, and the α alumina crystal phase fraction of the powder in the particle size region of 8 μm or more is from 30 to 70 mass %, more preferably from 35 to 60 mass %.

By adjusting the α alumina crystal phase fraction to such a range, an inorganic powder (alumina powder) having high thermal conductivity can be obtained.

The particle size distribution of the inorganic powder according to a preferred embodiment of the present invention can be determined by a known particle size distribution measuring apparatus. For example, a particle size measuring apparatus employing a laser diffraction/scattering system is preferably used and examples of the particle size distribution measuring apparatus which can be used for the measurement include Microtrac HRA (manufactured by Nikkiso K.K.) and SALD-2000J (manufactured by Shimadzu Corporation). Incidentally, assuming that the refractive index of water is 1.33 and when the inorganic powder is, for example, an aluminum oxide powder, a refractive index from 1.77 to 1.8 may be used.

The maximum particle size as used in the present invention is an accumulated 100% particle size in the cumulative particle size distribution of the inorganic powder and the average particle size is a median size and an accumulated 50% particle size in the cumulative particle size distribution of the inorganic powder. The mode size is a particle size showing a highest mode value in the frequency-size distribution of the inorganic powder.

The spheroidicity as used in the present invention indicates an average spheroidicity and this can be determined by the following method. An image of particles is photographed by a stereoscopic microscope, a scanning electron microscope or the like and taken into an image analyzing apparatus or the like. A projected area (a) and a contour circumferential length L₍ₐ₎ of an arbitrary particle are measured from the photograph and assuming that the area of a true circle having the same contour circumferential length as L₍ₐ₎ is (b), the following expression can be established.

(b)=π×(L₍ₐ₎/2π)²

Accordingly, the spheroidicity can be calculated by the following formula:

Spheroidicity=(a)/(b)=(a)×4π/(L₍ₐ₎)²

In this way, a certain number of particles are determined on the spheroidicity and the average value thereof is defined as the average spheroidicity. At this time, the calculation is preferably performed by using 200 or more particles.

As for the spheroidicity measuring method other than the above, the circularities of individual particles are quantitatively and automatically measured by a particle image analyzing apparatus such as “FPIA-2100” (manufactured by Sysmex Corp.), and the spheroidicity can be determined from the circularity by conversion according to the following formula:

Spheroidicity=(circularity)²

The spheroidization ratio as used in the present invention is a number frequency ratio of the spheroidicity of 1.0 in a so-called spheroidicity distribution. This ratio can be determined from the number frequency multiplication of the above-described circularities of particles quantitatively and automatically measured by a particle image analyzing apparatus or the like.

Other than this, particles are photographed by a scanning electron microscope at a predetermined magnification selected according to the size of powder particles (an arbitrary magnification of 150 to 1,000 times), the total number of particles of 5 μm or more and the number of unspheroidized particles are counted in one visual field, and the spheroidization ratio can calculated according to the following formula:

Spheroidization ratio=(total number−number of unspheroidized particles)/total number

As for the method of counting unspheroidized particles, any method may be used, such as visual inspection method by comparison using a previously prepared judgment sample or counting method using a known image analyzing apparatus.

The α alumina crystal phase fraction in the inorganic powder (alumina powder) is not particularly limited in its measuring method and may be measured by a known powder X-ray diffraction apparatus. An X-ray diffraction analysis with a CuKα radiation is performed under the conditions such that the slit is 0.3 mm, the scan speed is 1°/min and the scan range is 2θ=γto 70°, and assuming that the obtained peak (αalumina) height at 2θ=68.2° is A, the peak (intermediate alumina) height at 2θ=67.3° is B and the base line value at 2θ=69.5° as a background is C, the α alumina crystal phase fraction can be determined according to the following formula:

αAlumina crystal phase fraction=(A−C)/((A−C)+(B−C))×100

The aluminum metal content in the inorganic powder according to a preferred embodiment of the present invention is preferably 0.05 mass % or less, more preferably 0 to 0.01 mass %. In a case where an inorganic powder containing a large amount of aluminum metal is used, for example as a high thermally conductive filler for an insulating layer, a current short-circuit (dielectric breakdown) readily occurs between a circuit copper foil and a substrate when a high voltage is applied thereto, which may lead to destruction of the circuit and further the device using the circuit.

The method for measuring the concentration of aluminum metal in the inorganic powder according to a preferred embodiment of the present invention is not particularly limited, and any known inorganic analysis method may be employed. Preferably, the concentration is determined by subjecting the inorganic powder to extraction process by heating with hydrochloric acid and then subjecting the filtrate liquid to measurement of components soluble in the hydrochloric acid by using an ICP (high-frequency inductively coupled plasma) emission spectrophotometer. Examples of emission spectrophotometer usable in the measurement include ICPS-7500 (manufactured by Shimadzu Corporation).

The sulfate ion concentration in the inorganic powder according to a preferred embodiment of the present invention is preferably 15 ppm or less, more preferably 5 ppm or less. For example, in a case where an inorganic acid subjected to surface treatment with a silane coupling agent is used as a filler or in a case where a silicone-base material is used as an insulating resin compound, siloxane bonds are present in the vicinity of a silanol group on the powder surface or in the silicone resin itself, and the higher the concentration of the sulfate ion in the inorganic powder, the siloxane bond breaking is accelerated, resulting in generation of low-molecular siloxane gas. Siloxane bonds breaking occasionally deteriorates flexibility of the resin composition or strength in the connection interface between the resin and the powder particles. Furthermore, low-molecular siloxane may be volatilized and dispersed in a high-temperature and air-tight place like an inside of an apparatus and may be recrystallized and deposit as silica crystals on the surface of component parts and connection terminals of the apparatus. Such silica crystals are likely to become electrical insulators to cause problems such as imperfect connection, and therefore it is preferable that the amount of sulfate ions contained in the inorganic powder of the present invention be as small as possible.

The concentration of chlorine ion in the inorganic power according to a preferred embodiment of the present invention is preferably 15 ppm or less, more preferably 10 ppm or less. As above described in relation to sulfate ion, occasional deterioration of properties of the resin or imperfect connection in the circuit caused by siloxane bond breaking is true on the case of chlorine ion, and further the acid component may corrode or damage the insulating resin layer. Accordingly, for the purpose of obtaining high reliability in the insulating resin compound and the circuit board, it is preferable that the concentration of chlorine ion contained in the inorganic ion powder be as low as possible.

The method for measuring the concentrations of sulfate ions and chlorine ions in the inorganic powder of the present invention is not particularly limited, and any known separation analysis method useful for measurement on amount of trace inorganic anions and cations and organic acids may be employed. Preferably, the concentrations are determined by subjecting the inorganic powder to boiling extraction process with pure water and then subjecting the solution to measurement on water-soluble components by using ion chromatography. As an analysis apparatus, for example, Shodex (manufactured by SHOWA DENKO K.K.) can be employed.

The existence forms of sulfate ions and chlorine ions are not particularly limited, and some of the ions are assumed to be present in the inorganic powder in a nonionic state. In the present invention, the sulfate ion and the chlorine ion in the present invention can be defined as components extracted by boiling extraction process with pure water and detected as sulfate ion and chlorine ion by ion chromatography.

According to a preferred embodiment the present invention, the concentration of Fe₂O₃ in the inorganic powder is preferably 0.03 mass % by weight, more preferably 0.005 to 0.015 mass %. In the same way as aforementioned in relation to metal aluminum, the higher the concentration of Fe₂O₃, the more likely electrical short circuits are to occur between the circuit copper foil and the substrate. Accordingly, for the purpose of obtaining high reliability in the circuit board, it is preferable that the concentration of Fe₂O₃be as low as possible.

The method for measuring the concentration of Fe₂O₃ in the inorganic powder according to a preferred embodiment of the present invention is not particularly limited, and any known inorganic analysis method may be employed. Preferably, the concentration is determined by adding phosphoric acid to a sample of the inorganic powder, subjecting the sample to decomposition process by using a microwave acid decomposition apparatus, and then subjecting the resulting solution to measurement of the components by using an ICP (high-frequency inductively coupled plasma) emission spectrophotometer. Examples of emission spectrophotometer usable in the measurement include ICPS-7500 (manufactured by Shimadzu Corporation) as in the Al metal measurement.

It is preferable that the inorganic powder according to a preferred embodiment of the present invention contain virtually no particles of less than 50 nm. When an inorganic powder contains an excessive amount of particles of less than 50 nm, viscosity of resin compound filled with such an organic powder markedly increases, resulting in deterioration of properties of the inorganic powder which would otherwise have a good fillability. From this point of view, it is preferable that the inorganic powder according to a preferred embodiment of the present invention contain no such particles.

That “the inorganic powder contains virtually no particles of less than 50 nm” means that the average number of particles of less than 50 nm, which is figured out per microscopic field by counting numbers of particles of less than 50 nm in arbitrarily selected 100 or more fields photographed at a magnification of 50,000 by using a scanning electron microscope, is less than 50 or so. The smaller the number of particles of less than 50 nm, more preferable. However, if the average number of such particles is 50 or more, the effect of the invention is not sharply impaired, and such particles of 50 or so in number never hinders expression of effects of the present invention.

The inorganic powder according to a preferred embodiment of the present invention is preferably a powder subjected to a surface-hydrophobing treatment with a silane-based coupling agent or a titanate-based coupling agent. The method for practicing the surface-hydrophobing treatment is not particularly limited but examples thereof include known methods such as dry method using a stirring mixer or the like having a shearing force, wet slurry method of performing a dispersion treatment in an aqueous system, an organic solvent system or the like, and spray method using a fluid nozzle.

In practicing such a surface-hydrophobing treatment, in the case of a method involving a stirring force, the treatment may be performed by taking care not to cause collapse of the powder shape and appropriately selecting the conditions such as stirring time according to the particle size of the inorganic powder subjected to the surface-hydrophobing treatment, the kind of the silane-based or titanate-based coupling agent, and the objective properties of the powder.

The silane-based coupling agent for use in the surface-hydrophobing treatment is not particularly limited but preferred examples thereof include epoxy-based silanes such as β-(3,4-epoxycyclohexyl)ethyltrimethoxysilane and γ-glycidoxypropyltrimethoxysilane, amino-based silanes such as γ-aminopropyltriethoxysilane, γ-aminopropyltriethoxysilane, γ-aminopropyltrimethoxysilane and N-(β-aminoethyl)-γ-aminopropyltrimethoxysilane, and ureidopropyltriethoxysilane. These silane-based coupling agents may be used individually or in combination of plural species. The silane-based coupling agent may be selected by taking account of the adhering property and dispersibility of resin composition and inorganic powder constituting an insulating layer or the like.

The titanate-based coupling agent is also not particularly limited. Preferable examples thereof include tetra(2,2-diallyloxymethyl-1-butyl)-bis(ditridecyl-phosphite)titanate, tetraoctyl-bis(ditridecyl-phosphite)titanate, tetraisopropyl-bis(ditridecyl-phosphite)titanate, bis(dioctylpyrophosphate)-oxyacetatetitanate, isopropyltri(N-aminoethyl.aminoethyl) titanate, isopropyltriisostearoyltitanate, isopropyltri-i-dodecylbenzene sulfonyltitanate, isopropyltri-n-dodecylbenzene sulfonyltitanate, isopropyl-tri(dioctylpyro-dioctylpyrophosphate)titanate, bis(dioctylpyrophosphate)ethylenetitanate, isopropyltricumylphenyltitanate and dicumylphenyloxyacetatetitanate, and these may be selected by taking account of the adhering property and dispersibility of resin and inorganic powder constituting an insulating layer or the like.

Specific preferred examples of the organic polymer (resin) used as the matrix for the resin composition filled with the inorganic powder according to a preferred embodiment of the present invention include, but are not limited to, known resins such as epoxy resin, polyimide resin, silicone resin, polyolefin (e.g. polyethylene, polypropylene, polystyrene), melamine resin, urea resin, phenol resin, polyethylene terephthalate, polyester (e.g., unsaturated polyester), polyamide (e.g., nylon 6, nylon 66, aramid), polybutadiene, polyester, polyvinyl chloride, polyvinylidene chloride, polyethylene oxide, polyethylene glycol, polyvinyl alcohol, vinyl acetal resin, polyacetate, ABS resin, vinyl acetate resin, cellulose and cellulose derivatives (e.g., rayon), polyurethane, polycarbonate, urea resin, fluororesin, polyvinylidene fluoride, celluloid, chitin, starch sheet, acryl resin and alkyd resin, and a mixture thereof. These may be used individually or in combination of plural species.

Among these, epoxy resin and polyimide resin are preferred because the adhesive strength to a metal plate or foil is relatively strong and the affinity for the inorganic powder is relatively high.

In the aforementioned resin composition of the present invention, a curing accelerator and the like may be used, if desired. The curing accelerator is not particularly limited as long as it reacts with and thereby cures the resin used, but preferred known examples of the accelerator which reacts with and thereby cures the epoxy resin include phenol, cresol, imidazole, xylenol, resorcinol, chlorophenol, tert-butylphenol, nonylphenol, isopropylphenol, bisphenol compounds such as bisphenol A and bisphenol S, and acid anhydrides such as maleic anhydride. The curing accelerator may be selected by taking account of reactivity with the resin used.

Methods for preparing the resin composition filled with the inorganic powder in the present invention are not particularly limited. It is preferable that the resin composition be uniformly kneaded with the powder by using centrifugal kneading machine, revolutionary/rotary kneading machine, roll mill, Banbury mixer or kneader. It is more preferable that the kneading be performed while defoaming the resin composition by using a kneading apparatus having defoaming function.

The film formation method of the resin composition according to a preferred embodiment of the present invention is not particularly limited, but a doctor blade method or depending on the resin compound viscosity, an extrusion method, a press method, a calender roll method or the like is preferably used.

The evaluation of the resin compound viscosity as an index showing the flowability of the inorganic powder according to a preferred embodiment of the present invention and the evaluation of the breakdown voltage characteristics of the resin composition filled with the powder and formed into a thin-film sheet can be performed by the evaluation methods described in Examples.

The inorganic powder according to a preferred embodiment of the present invention is a powder having a specific particle size distribution and preferably subjected to a surface-hydrophobing treatment and by virtue of such specificity, provides advantageous effects that even a powder having a low spheroidicity and giving a high resin compound viscosity can be filled at a high density in a resin composition and by using such an inorganic powder as one of the components, a resin composition having excellent thermal conductivity and exhibiting excellent breakdown voltage characteristics when formed into a thin-film resin sheet with a thickness of 40 to 90 μm can be obtained.

A circuit board for mounting on automobiles, a circuit board for mounting on electronic devices, a member for radiating heat inside electronic devices, and a high thermally conductive member for electronic components can be obtained through a known method, by using the resin composition comprising the inorganic powder according to a preferred embodiment of the present invention. The high thermally conductive member for electronic components may be a sheet-like member capable of serving also as an insulating adhesive layer and may be used in a metal base circuit board, a metal core-type circuit board or a structure body thereof (see, for example, Denshi Gijutsu, extra edition, pp. 39-50 (December, 1985) and Circuit Technology, Vol. 5, No. 2, pp. 96-103 (1990)).

Furthermore, a structure body of a high thermally conductive metal member-integrated electronic component, where a heat generating electronic component and a high thermally conductive metal member are bonded, can also be formed by using a known method.

Moreover, it is possible to form an LED circuit board or a structure body thereof by processing the resin composition filled with the inorganic powder of the present invention into paste or gel and applying it as a heat-radiating encapsulant or a heat-radiating underfill agent for an electronic component having a heater element such as LED.

Specifically, when the resin is applied to LED circuit boards for room lights or indicator light in automobiles and structure bodies thereof, LED circuit boards or structure bodies for electronics devices such as personal computers, DVD players and color printers, home electronics devices such as televisions, mobile electronics devices such as PDA and cellular phones, large-area full-color display devices for outdoors, signal light devices, interior lighting devices, optical communication devices, medical devices and measurement devices, it usefully contributes to higher technical advantages in thermal conductivity and insulation of the devices. Particularly, in a case of applying the resin composition to a high luminance LED where LED devices are integrated at a high density for the purpose of heat radiation and cooling, an excellent functionality is exhibited, and therefore the resin composition of the present invention can be efficiently used in indicator devices using plane emission.

Thus, the high thermally conductive member according to a preferred embodiment of the present invention can contribute to enhancement in luminance of LED boards.

It is also possible to form a structure body where a heat generating electronic component and a high thermally conductive metal member are bonded by using the heat radiating member according to a preferred embodiment of the present invention, thereby contributing to higher technical advantages in various electronics devices.

### BEST MODE FOR CARRYING OUT THE INVENTION

The present invention is described in greater detail below by referring to Examples and Comparative Examples, but the present invention is not limited to these Examples.

### EXAMPLES 1 TO 8

Aluminum Oxide Powders A, B, C, D, E, F, G and H were prepared by previously applying a surface-hydrophobing treatment with γ-glycidoxypropyltrimethoxysilane (A-187, produced by Nippon Unicar Co., Ltd.) as the silane coupling agent and then adjusting the particle size distribution conditions as shown in Table 1.

The powder was kneaded and filled in a resin component under predetermined conditions and the composition was formed into a film by a doctor blade method to have a thickness of about 60 μm or less after dry-curing.

The thin-film resin sheet dry-cured under predetermined drying conditions was measured on the dielectric breakdown strength. The dielectric breakdown strength was measured based on the dielectric breakdown voltage test method prescribed in JIS C2110. For evaluating the resin compound viscosity of the aluminum oxide powders shown in Table 1, the epoxy resin viscosity was measured.

As seen from the results shown in Table 1, in case of particles having a spheroidicity of less than 0.89, the epoxy resin viscosity was from 1,000 to 1,400 P and a dielectric breakdown strength of 67 to 93 kV/mm could be obtained in films having a thickness of 45 to 55 μm (Examples 5 to 8). Also, even when a low-spheroidicity powder having a spheroidicity of less than 0.81 was used and the viscosity was elevated as the epoxy resin viscosity became 5,000 P or more, a dielectric breakdown strength of 39 to 78 kV/mm could be obtained with a film thickness of 44 to 53 pm (Examples 1 to 4).

The kneading/filling conditions of powder and resin and film-forming/drying conditions in the preparation of thin-film resin sheet, and the methods for measuring the breakdown voltage of sheet and measuring the epoxy resin viscosity are described below.

### (1) Kneading/filling Conditions of Powder and Resin

| | | |
|---|---|---|
| Powder: | 25 | g |
| Resin: epoxy resin compound | 10 | g |
| Curing agent: imidazole | 0.1 | g |

This mixture was kneaded by using a revolution and rotation hybrid mixing-type defoaming kneader (AR-250, manufactured by Thinky Corp.) under the conditions that the kneading time was 5 minutes and the defoaming time was 1 minute.

### (2) Film-Forming/Drying Conditions

The kneaded slurry obtained above was film-formed according to a doctor blade method by using an automatic film coater (manufactured by SEPRO) and a blade edge (75 μm) and immediately dried through three stages in a constant-temperature and constant-humidity oven, that is, at 40 to 50° C. for 30 minutes or more, at 120° C. for 15 minutes and at 180° C. for 30 minutes.

### (3) Method for Measuring Dielectric Breakdown Strength

The thin-film resin sheet obtained after drying was measured according to the dielectric breakdown voltage test method prescribed in JIS C2110 at an applied voltage of AC 5 kV by using a breakdown voltage tester (Model TOS-8870A, manufactured by Kikusui Electronics Corp.).

### (4) Method for Measuring Epoxy Resin Viscosity

250 Parts by mass of powder and 100 parts by mass of epoxy resin (epoxy resin AER-250, produced by Asahi Kasei Chemicals Corp.) were kneaded by a kneader and after adjusting it to 25° C. in a constant-temperature water bath, the viscosity was measured by a BH-type viscometer.

### (5) Method for Measuring Metal Aluminum Concentration

The inorganic powder was subjected to extraction process by heating with hydrochloric acid and then the components soluble in the hydrochloric acid in the filtrate liquid was measured by using an ICP (high-frequency inductively coupled plasma) emission spectrophotometer. ICPS-7500 (manufactured by Shimadzu Corporation) was employed as the analysis apparatus.

### (6) Method for Measuring Sulfate Ion and Chlorine Ion Concentrations

The inorganic powder was subjected to boiling extraction process with pure water and then the water-soluble components in the solution were measured by using ion chromatography. Shodex (manufactured by SHOWA DENKO K.K.) was employed as the analysis apparatus.

### (7) Method for Measuring Fe₂O₃ Concentration

After adding phosphoric acid to a sample of the inorganic powder and subjecting the sample to decomposition process by using a microwave acid decomposition apparatus, the components in the resulting solution were measured by using an ICP emission spectrophotometer. As in the case of aluminum measurement, ICPS-7500 (manufactured by Shimadzu Corporation) was employed as the analysis apparatus.

### COMPARATIVE EXAMPLES 1 TO 4

Aluminum Oxide Powders I, J, K and L shown in Table 2 each was filled in a resin, formed into a thin-film resin sheet and measured on the dielectric breakdown strength in the same procedures and conditions as in Examples and also, the epoxy resin viscosity of each powder was measured.

As seen from the results in Table 2, the dielectric breakdown strength was from 28 to 32 kV/mm in all samples with a film thickness of 47 to 50 μm.

### REFERENCE EXAMPLE 1

As an example of the case where the aluminum oxide powder has a very high spheroidicity, Aluminum Oxide Powder I (a powder obtained by mixing 20 mass % of spherical aluminum oxide “Admafine® AO-502” and 80 mass % of “Admafine® AO-509”, produced by Admatechs Co., Ltd.) shown in Table 3 was prepared.

A thin-film resin sheet was formed in the same manner as in Examples and measured on the dielectric breakdown strength. Also, the epoxy resin viscosity of the powder was measured.

As seen in Table 3, it was confirmed that in the case of the commercially available high-spheroidicity powder, the epoxy resin viscosity was as low as 1,080 P and a dielectric breakdown strength of 39 kV/mm was obtained with a film thickness of 55 μm.

TABLE 1

| | | | Examples | | | |
|---|---|---|---|---|---|---|
| | | | 1 | 2 | 3 | 4 |
| Name of powder | | | A | B | C | D |
| Particles | percentage | mass % | 52.1 | 52.1 | 55.2 | 55.2 |
| of 8 μm or | spheroidicity | — | 0.78 | 0.78 | 0.78 | 0.78 |
| more | spheroidization ratio | — | 0.75 | 0.75 | 0.75 | 0.75 |
| | α alumina crystal | mass % | 40 | 40 | 40 | 40 |
| | fraction | | | | | |
| Particles | percentage | mass % | 10.3 | 5.4 | 5.3 | 10.2 |
| of less | spheroidicity | — | 0.70 | 0.70 | 0.70 | 0.70 |
| than 2 μm | spheroidization ratio | — | 0.10 | 0.10 | 0.10 | 0.10 |
| | α alumina crystal | mass % | 99 | 99 | 99 | 99 |
| | fraction | | | | | |

| | | | | | |
|---|---|---|---|---|---|
| Mode size in the region of less than 2 μm | μm | 0.34 | 0.34 | 0.34 | 0.34 |
| Percentage of particles of 2 to 8 μm | mass % | 37.6 | 42.5 | 39.5 | 34.6 |
| Number of peaks in distribution | | 2 | 2 | 2 | 2 |
| Maximum particle size | μm | 62.2 | 62.2 | 62.2 | 62.2 |
| Average particle size | μm | 8.2 | 9.5 | 9.3 | 9.2 |
| Mode size | μm | 14.27 | 14.27 | 14.27 | 14.27 |
| Spheroidicity (average) | — | 0.79 | 0.78 | 0.78 | 0.77 |
| Spheroidization ratio (average) | — | 0.69 | 0.68 | 0.72 | 0.68 |
| α Alumina crystal fraction | mass % | 43 | 44 | 41 | 46 |
| Aluminum concentration | mass % | <0.01 | <0.01 | <0.01 | <0.01 |
| SO₄²⁻ ion concentration | ppm | <1 | <1 | <1 | <1 |
| Cl⁻ ion concentration | ppm | <5 | <5 | <5 | <5 |
| Fe₂O₃ concentration | mass % | 0.01 | 0.01 | 0.01 | 0.01 |
| Thickness of sheet | μm | 47 | 48 | 44 | 53 |
| Dielectric breakdown strength | kV/mm | 45 | 39 | 41 | 78 |
| Epoxy resin viscosity | P | >5000 | >5000 | >5000 | >5000 |

| | | | Examples | | | |
|---|---|---|---|---|---|---|
| | | | 5 | 6 | 7 | 8 |
| Name of powder | | | E | F | G | H |
| Particles | percentage | mass % | 85.5 | 80.7 | 76.0 | 71.2 |
| of 8 μm or | spheroidicity | — | 0.89 | 0.89 | 0.89 | 0.89 |
| more | spheroidization ratio | — | 0.90 | 0.90 | 0.90 | 0.90 |
| | α alumina crystal | mass % | 55 | 55 | 55 | 55 |
| | fraction | | | | | |
| Particles | percentage | mass % | 9.9 | 14.9 | 19.1 | 23.9 |
| of less | spheroidicity | — | 0.70 | 0.70 | 0.70 | 0.70 |
| than 2 μm | spheroidization ratio | — | 0.10 | 0.10 | 0.10 | 0.10 |
| | α alumina crystal | mass % | 99 | 99 | 99 | 99 |
| | fraction | | | | | |

| | | | | | |
|---|---|---|---|---|---|
| Mode size in the region of less than 2 μm | μm | 0.34 | 0.34 | 0.34 | 0.34 |
| Percentage of particles of 2 to 8 μm | mass % | 4.6 | 4.4 | 4.9 | 4.9 |
| Number of peaks in distribution | | 2 | 2 | 2 | 2 |
| Maximum particle size | μm | 31.1 | 31.1 | 31.1 | 31.1 |
| Average particle size | μm | 9.6 | 9.1 | 8.6 | 8.1 |
| Mode size | μm | 11.0 | 11.0 | 11.0 | 11.0 |
| Spheroidicity (average) | — | 0.87 | 0.88 | 0.85 | 0.84 |
| Spheroidization ratio (average) | — | 0.81 | 0.81 | 0.72 | 0.68 |
| a Alumina crystal fraction | mass % | 59 | 62 | 64 | 66 |
| Aluminum concentration | mass % | <0.01 | <0.01 | <0.01 | <0.01 |
| SO₄²⁻ ion concentration | ppm | <1 | <1 | <1 | <1 |
| Cl⁻ ion concentration | ppm | <5 | <5 | <5 | <5 |
| Fe₂O₃ concentration | mass % | 0.01 | 0.01 | 0.01 | 0.01 |
| Thickness of sheet | μm | 45 | 47 | 52 | 55 |
| Dielectric breakdown strength | kV/mm | 83 | 93 | 80 | 67 |
| Epoxy resin viscosity | P | 1240 | 1390 | 1010 | 1060 |

TABLE 2

| | | | Comparative Examples | | | |
|---|---|---|---|---|---|---|
| | | | 1 | 2 | 3 | 4 |
| Name of powder | | | I | J | K | L |
| Particles | percentage | mass % | 42.9 | 42.9 | 49.0 | 49.0 |
| of 8 μm or | spheroidicity | — | 0.78 | 0.78 | 0.78 | 0.78 |
| more | spheroidization ratio | — | 0.75 | 0.75 | 0.75 | 0.75 |
| | α alumina crystal | mass % | 40 | 40 | 40 | 40 |
| | fraction | | | | | |
| Particles | percentage | mass % | 20.2 | 10.5 | 20.1 | 0.6 |
| of less | spheroidicity | — | 0.70 | 0.70 | 0.70 | 0.95 |
| than 2 μm | spheroidization ratio | — | 0.10 | 0.10 | 0.10 | 0.90 |
| | α alumina crystal | mass % | 99 | 99 | 99 | — |
| | fraction | | | | | |

| | | | | | |
|---|---|---|---|---|---|
| Mode size in the region of less than 2 μm | μm | 0.34 | 0.34 | 0.34 | — |
| Percentage of particles of 2 to 8 μm | mass % | 36.9 | 46.6 | 30.9 | 50.4 |
| Number of peaks in distribution | | 2 | 2 | 2 | 1 |
| Maximum particle size | μm | 62.2 | 62.2 | 62.2 | 62.2 |
| Average particle size | μm | 7.3 | 7.6 | 7.9 | 8.5 |
| Mode size | μm | 14.27 | 14.27 | 14.27 | 14.27 |
| Spheroidicity (average) | — | 0.78 | 0.81 | 0.76 | 0.81 |
| Spheroidization ratio (average) | — | 0.62 | 0.71 | 0.60 | 0.78 |
| α Alumina crystal fraction | mass % | 49 | 40 | 52 | 34 |
| Aluminum concentration | mass % | <0.01 | <0.01 | <0.01 | <0.01 |
| SO₄²⁻ ion concentration | ppm | <1 | <1 | <1 | <1 |
| Cl⁻ ion concentration | ppm | <5 | <5 | <5 | <5 |
| Fe₂O₃ concentration | mass % | 0.01 | 0.01 | 0.01 | 0.01 |
| Thickness of sheet | μm | 50 | 50 | 49 | 47 |
| Dielectric breakdown strength | kV/mm | 28 | 29 | 30 | 32 |
| Epoxy resin viscosity | P | >5000 | 4330 | >5000 | 3340 |

TABLE 3

| | | | Reference |
|---|---|---|---|
| | | | Example 1 |
| Name of powder | | | I |
| Particles | percentage | mass % | 50.8 |
| of 8 μm or | spheroidicity | — | 0.95 |
| more | spheroidization ratio | — | 0.95 |
| | α alumina crystal fraction | mass % | 38 |
| Particles | percentage | mass % | 33.0 |
| of less | spheroidicity | — | 0.95 |
| than 2 μm | spheroidization ratio | — | 0.95 |
| | α alumina crystal fraction | mass % | 5 |

| | | |
|---|---|---|
| Mode size in the region of less than 2 μm | μm | 0.34 |
| Percentage of particles of 2 to 8 μm | mass % | 16.2 |
| Number of peaks in distribution | | 2 |
| Maximum particle size | μm | 88.0 |
| Average particle size | μm | 9.1 |
| Mode size | μm | 20.17 |
| Spheroidicity (average) | — | 0.95 |
| Spheroidization ratio (average) | — | 0.95 |
| α Alumina crystal fraction | mass % | 31 |
| Aluminum concentration | mass % | 0.18 |
| SO₄²⁻ ion concentration | ppm | 18 |
| Cl⁻ ion concentration | ppm | <5 |
| Fe₂O₃ concentration | mass % | 0.09 |
| Thickness of sheet | μm | 55 |
| Dielectric breakdown strength | kV/mm | 39 |
| Epoxy resin viscosity | P | 1020 |

### INDUSTRIAL APPLICABILITY

The inorganic powder according to a preferred embodiment of the present invention can be filled at a high density in a resin even when having low spheroidicity and spheroidization ratio and therefore, can enhance the thermal conduction and dielectric breakdown strength of the resin composition.

The thin-film resin sheet using the inorganic powder according to a preferred embodiment of the present invention can have high breakdown voltage characteristics, so that a resin composition and a thin-film resin sheet which are excellent in the thermal conductivity, heat radiation characteristics and breakdown voltage characteristics, and a circuit board and a structure body each using the resin composition or sheet as the high thermally conductive member can be provided.

That is, the inorganic powder according to a preferred embodiment of the present invention is a powder having a specific particle size distribution, preferably controlled to contain impurities in a specific concentration range, and more preferably being subjected to a surface-hydrophobing treatment and by virtue of such specificity, provides advantageous effects that even a powder having a low spheroidicity and giving a high resin compound viscosity can be filled at a high density in a resin and by using this inorganic powder as one of the components, a resin composition having excellent thermal conductivity and exhibiting excellent breakdown voltage characteristics when formed into a thin-film resin sheet with a thickness of 40 to 90 μm can be obtained.

Accordingly, when the resin composition of the present invention is used, a circuit board for mounting on automobiles, a circuit board for mounting on electronic devices, a member for radiating heat inside electronic devices, and a high thermally conductive member for electronic components, which are excellent in the heat radiation characteristics and breakdown voltage characteristics, can be obtained. In this case, the high thermally conductive member for electronic components may be a sheet-like member capable of serving also as an insulating adhesive layer.

Also, when the resin composition of the present invention is used, even in the case of using it as a high thermally conductive member serving also as an insulating adhesive layer or the like in a metal base circuit board, a metal core-type circuit board or a structure body thereof, excellent functionality is exerted.

Moreover, by processing the resin composition filled with the inorganic powder of the present invention into paste or gel and applying it as a heat-radiating encapsulant, a heat-radiating underfilling agent or the like for an electronic component which, as in LEDs, includes a heat generating element, when used in LED circuit boards for room lights in automobiles and LED circuit boards or structure bodies thereof for indicator lights which are mounted in an automobile, LED circuit boards or structure bodies for electronics devices such as personal computers, DVD players and color printers, home electronics devices such as televisions, mobile electronics devices such as PDA and cellular phones, large-area full-color display devices for outdoors, signal light devices, interior lighting devices, optical communication devices, medical devices and measurement devices, the resin composition usefully contributes to higher technical advantages in thermal conductivity and insulation of the devices. Particularly, in a case of applying the resin composition to a high luminance LED where LED devices are integrated at a high density for the purpose of heat radiation and cooling, an excellent functionality is exhibited, and therefore the resin composition of the present invention can be efficiently used in indicator devices using plane emission. Thus, the high thermally conductive member according to the present invention can contribute to enhancement in luminance of LED boards.

Furthermore, a structure body of a high thermally conductive metal member-integrated electronic component, where a heat generating electronic component and a high thermally conductive metal member are bonded by using such a high thermally conductive member, can be formed and this can contribute to fabrication of various high-performance electronic devices.

1. An inorganic powder having a frequency-size distribution with multiple peaks, wherein the peaks are present at least in the particle size regions from 0.2 to 2 μm and from 2 to 63 μm.

2. The inorganic powder as claimed in claim 1, wherein the maximum particle size is 63 μm or less, the average particle size is from 4 to 30 μm, and the mode size is from 2 to 35 μm.

3. The inorganic powder as claimed in claim 1, wherein the percentage of particles having a particle size of less than 2 μm is from 0 to 20 mass % and the mode size of particles having a particle size of less than 2 μm is from 0.25 to 1.5 μm.

4. The inorganic powder as claimed in claim 1, wherein the percentage of particles having a particle size of 8 μm or more is from 44 to 90 mass %.

5. The inorganic powder as claimed in claim 1, wherein the percentage of particles having a particle size of from 2 to 8 μm is from 0 to 15 mass %.

6. The inorganic powder as claimed in claim 1, wherein the percentage of particles having a particle size of from 2 to 8 μm is from 32 to 45 mass %.

7. The inorganic powder as claimed in claim 1, wherein the spheroidicity is from 0.68 to 0.95 and the spheroidization ratio is from 0.63 to 0.95.

8. The inorganic powder as claimed in claim 1, wherein the spheroidicity of particles having a particle size of less than 2 μm is from 0.5 to 0.95 and the spheroidization ratio thereof is from 0 to 0.9.

9. The inorganic powder as claimed in claim 1, wherein the spheroidicity of particles having a particle size of 8 μm or more is from 0.7 to 0.95 and the spheroidization ratio thereof is from 0.7 to 0.95.

10. The inorganic powder as claimed in claim 1, wherein the thermal conductivity of the inorganic powder in the single crystal state is 30 W/m.K or more.

11. The inorganic powder as claimed in claim 1, which is an alumina powder.

12. The inorganic powder as claimed in claim 11, wherein the α alumina crystal phase fraction of the alumina powder is from 30 to 75 mass %.

13. The inorganic powder as claimed in claim 11, wherein the ax alumina crystal phase fraction of the particle of less than 2 μm is from 90 to 100 mass %.

14. The inorganic powder as claimed in claim 11, wherein the cc alumina crystal phase fraction of the particle of 8 μm or more is from 30 to 70 mass %.

15. The inorganic powder as claimed in claim 1, wherein the content of metal aluminum is 0.05 mass % or less.

16. The inorganic powder as claimed in claim 1, wherein the content of sulfate ion is 15 ppm or less.

17. The inorganic powder as claimed in claim 1, wherein the content of chlorine ion is 15 ppm or less.

18. The inorganic powder as claimed in claim 1, wherein the content of Fe₂O₃ is 0.03 mass % or less.

19. The inorganic powder as claimed in claim 1, which contains substantially no particles of less than 50 nm.

20. The inorganic powder as claimed in claim 1, which is subjected to surface-hydrophobing treatment with at least one surface-treating agent selected from silane-based coupling agent and titanate-based coupling agent.

21. A resin composition filled with the inorganic powder described in claim 1.

22. The resin composition as claimed in claim 21, wherein from 50 to 90 mass % of the inorganic powder is filled.

23. The resin composition as claimed in claim 21, wherein when the resin composition is formed into a thin-film insulating resin composition with a thickness of 40 to 90 μm, the dielectric breakdown strength as measured by a dielectric breakdown voltage test prescribed in JIS C2110 is 39 kV/mm or more.

24. A circuit board for mounting on automobiles, using the resin composition described in claim 21.

25. A circuit board for mounting on electronic devices, using the resin composition described in claim 21.

26. A high thermally conductive member for installation in electronic devices, using the resin composition described in claim 21.

27. A high thermally conductive member for electronic components, using the resin composition described in claim 21.

28. The high thermally conductive member as claimed in claim 26, which is in a sheet form.

29. The high thermally conductive member as claimed in claim 26, which is in a form of gel or paste.

30. The high thermally conductive member as claimed in claim 26, which is underfill-agent type member.

31. The high thermally conductive member as claimed in claim 26, which is applied by coating onto a heating portion of an elemental device.

32. A metal-based circuit board, a metal core-type circuit board and a structure body thereof, wherein the resin composition described in claim 21 is used as a high thermally conductive member serving also as an insulating adhesive layer or the like.

33. A structure body of a high thermally conductive metal member-integrated electronic component, wherein a heat generating electronic component and a high thermally conductive metal member are bonded by using the high thermally conductive member described in claim 26.

34. An LED circuit board using the high thermally conductive member described in claim 26.

35. An automobile using the circuit board claimed in claim 32.

36. An electronic product using the circuit board claimed in claim 32.

37. A light indicator using the circuit board claimed in claim 32.

38. A display device using the circuit board claimed in claim 32.
